(19) United States
(12) Patent Application Publication
(10) Pub. No.: US 2024/0203919 A1
(43) Pub. Date: Jun. 20, 2024

(54) INTEGRATED CIRCUIT HAVING EXPOSED LEADS

(71) Applicant: TEXAS INSTRUMENTS INCORPORATED, Dallas, TX (US)

(72) Inventors: JOHN CARLO CRUZ MOLINA, Bataan (PH); RAFAEL JOSE LIZARES GUEVARA, Makati Metro Manila (PH)

(21) Appl. No.: 18/082,285

(22) Filed: Dec. 15, 2022

(51) Int. Cl. H01L 23/00; H01L 21/56; H01L 21/78; H01L 23/31

(52) U.S. Cl. CPC H01L 24/13; H01L 21/561; H01L 21/78; H01L 23/31; H01L 24/03; H01L 24/05; H01L 24/11; H01L 2224/02175; H01L 2224/02185; H01L 2224/0219; H01L 2224/03013; H01L 2224/0401; H01L 2224/05147; H01L 2224/05166; H01L 2224/05184; H01L 2224/05647; H01L 2224/11849; H01L 2224/13017; H01L 2224/13147; H01L 2224/13551; H01L 2224/136

(57) ABSTRACT

An electronic device that includes a semiconductor substrate and a conductive structure disposed over the semiconductor substrate. An insulator layer overlies the semiconductor substrate and includes a tapered opening that overlies a portion of the conductive structure. A flanged conductive column that includes a base portion is disposed in the tapered opening and is coupled to the portion of the conductive structure. The flanged conductive column further includes a flanged portion that is configured to be exposed to provide a conductive contact to the electronic device.

### TECHNICAL FIELD

The present disclosure relates to an electronic device, and more specifically to an integrated circuit having exposed leads.

### BACKGROUND

Different integrated circuits (IC) have advantages and disadvantages. For example, a quad flat no-lead (QFN) package has better thermal performance than a wafer-level chip-scale package (WCSP). A WCSP, however, has a lower resistance than a QFN package due to its simple configuration. QFN packages also require connecting wire bonds from a die to a leadframe. The WCSP eliminates the need for bonding wires and a leadframe that are present in the QFN package. WCSP's, however, are mounted to a board (e.g., printed circuit board) via a solder ball. The process to deposit the solder ball in the WCSP requires several complex steps, For example, the process may include first depositing a seed layer, photoresist lithography, depositing an under bump metallization layer, stripping the photoresist layer, etching the seed layer, and finally depositing the solder ball.

### SUMMARY

In described examples, an electronic device that includes a semiconductor substrate and a conductive structure disposed over the semiconductor substrate. An insulator layer overlies the semiconductor substrate and includes a tapered opening that overlies a portion of the conductive structure. A flanged conductive column that includes a base portion is disposed in the tapered opening and is coupled to the portion of the conductive structure. The flanged conductive column further includes a flanged portion that is configured to be exposed to provide a conductive contact to the electronic device.

In another described example, a method of forming an electronic device includes forming a conductive structure over a semiconductor substrate and depositing an insulator layer over the conductive structure and the semiconductor substrate. A tapered opening is etched in the insulator layer that overlies the conductive structure. A flanged conductive column is provided that includes a base portion and a flanged portion where the base portion of the flanged conductive column is disposed in the tapered opening with the tapered opening extending outward away from the conductive structure to form a conductive contact of the electronic device. A solder reflow process is performed on the electronic device to align and solder the base portion of the flanged conductive column to the conductive structure.

In still another described example, a method of fabricating electronic devices includes forming respective conductive structures associated with respective electronic devices over a semiconductor wafer and depositing an insulator layer over the respective conductive structures and the semiconductor wafer. Tapered openings are etched in a portion of the insulator layer overlying associated respective conductive structures associated with respective electronic devices. A plurality of solder coated flanged conductive columns are provided that include a base portion and a flanged portion where the base portion of the flanged conductive columns is disposed in respective tapered opening with the tapered portions extending outward away from the respective conductive structure to form a conductive contact of a respective electronic device. A solder reflow process is performed to align and solder the base portions of the respective flanged conductive columns to the respective conductive structures. The flanged conductive column is encapsulated with an encapsulation material layer covering the insulator layers, the base portions and a portion of the flange portions of the respective flanged conductive column leaving a mounting surface of the flanged conductive column exposed and extending beyond the encapsulation material layer to provide a conductive contact to the respective electronic devices. The electronic devices are singulated by cutting through the encapsulation material layer, the insulating layer and semiconductor wafer to form individual electronic devices.

### BRIEF DESCRIPTION OF THE DRAWINGS

FIG. 1A illustrates a cross-sectional view of an example electronic device.

FIG. 1B is a top view of a flanged conductive column of the example electronic device of FIG. 1A.

FIG. 2A illustrates a cross-sectional view of a substrate including a seed layer in the early stages of fabrication of the electronic device of FIG. 1A.

FIG. 2B illustrates a cross-sectional view of the electronic device of FIG. 2A after a formation of a photoresist material layer.

FIG. 2C illustrates a cross-sectional view of the electronic device of FIG. 2B after undergoing a patterning process.

FIG. 2D illustrates a cross-sectional view of the electronic device of FIG. 2C after an electroplating procedure.

FIG. 2E illustrates a cross-sectional view of the electronic device of FIG. 2D after stripping of the photoresist material layer.

FIG. 2F illustrates a cross-sectional view of the electronic device of FIG. 2E after an etching process.

FIG. 2G illustrates a cross-sectional view of the electronic device of FIG. 2F after deposition of an insulator layer.

FIG. 2H illustrates a cross-sectional view of the electronic device of FIG. 2G after undergoing a patterning process.

FIG. 2I illustrates a cross-sectional view of the electronic device of FIG. 2H after deposition of flux.

FIG. 2J illustrates a cross-sectional view of the electronic device of FIG. 2I after depositing a flanged conductive column into the flux.

FIG. 2K illustrates a cross-sectional view of the electronic device of FIG. 2J after undergoing a solder reflow process and a flux wash process.

FIG. 2L illustrates a cross-sectional view of FIG. 2K after undergoing formation of an encapsulation material layer.

FIG. 2M illustrates a cross-sectional view of two electronic devices prior to singulation.

FIG. 2N illustrates a cross-sectional view of the two electronic devices of FIG. 2M after singulation.

FIG. 2O illustrates a stencil placed over the substrate that includes an array of the electronic devices.

FIG. 2P is a cross-sectional view of the stencil and substrate of FIG. 2O.

FIG. 2Q is a diagram illustrating a process of picking an placing an array of the flanged conductive columns onto an array of the electronic devices.

FIG. 2R is a top view illustrating all the arrays of flanged conductive columns placed onto all the arrays of electronic devices.

### DETAILED DESCRIPTION

The miniaturization and the simplicity of fabricating integrated circuit (IC) products has become more and more important. For example, quad flat no-lead (QFN) packages require a fabrication process that includes connecting wire bonds to a leadframe. Wafer-level chip-scale packages WCSP's eliminate the need for wire bonds and the leadframe, but mount to a board (e.g., printed circuit board) via a solder ball. The process to deposit the solder ball in the WCSP requires several complex steps, For example, the process may include first depositing a seed layer, overlying a photoresist layer, depositing an under bump metallization (UBM) layer, stripping the photoresist layer, etching the seed layer, and finally depositing the solder ball. The QFN package, however, has a better thermal performance than the WCSP whereas, the WCSP has a lower resistance than a QFN package due to its simple configuration. Thus, the need exists for an IC package that has a straight-forward configuration that reduces fabrication process steps and that includes the advantages of both the QFN package and the WCSP.

Disclosed herein is an electronic device and a method of fabricating the electronic device that is a combination of the QFN package and the WCSP. The electronic device has a simpler configuration that requires less fabrication steps than the WCSP while having the advantages of both the QFN package and the WCSP. The electronic device is a flip chip QFN type package that does not require wire bonds or a leadframe required in a QFN package. In addition, the electronic device does not require the UBM layer or the solder ball required in a WCSP. Still further, the back grinding process is eliminated due to the exposed contacts.

Rather, the electronic device includes a substrate that includes electronic circuitry integrated therein and a conductive structure deposited over a portion of the substrate. An insulator layer overlies the substrate and includes a tapered opening to thereby expose a portion of a surface of the conductive structure. A flanged conductive column is disposed in the tapered opening. The flanged conductive column is coated with solder to thereby couple the flanged conductive column to the exposed portion of the conductive structure. A flanged portion of the flanged conductive column is exposed above an encapsulation material layer to thereby provide a conductive contact to the electronic device.

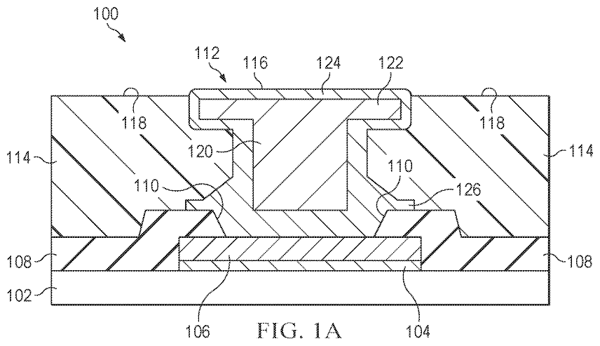

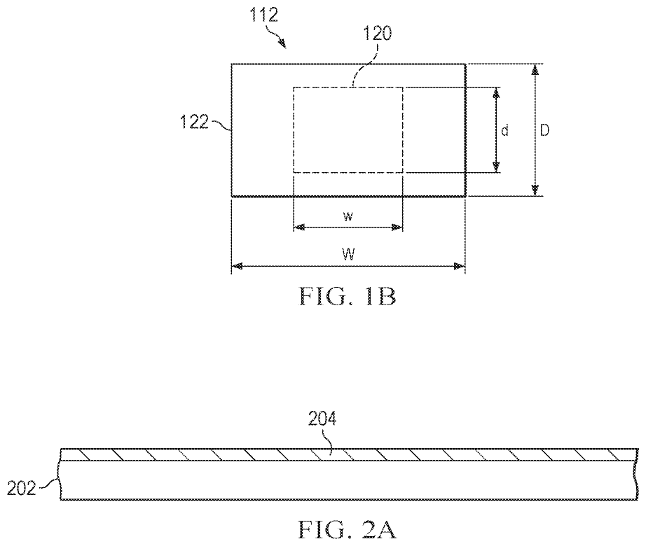

FIG. 1A is a cross-sectional view of an example electronic device (e.g., flip chip QFN package) 100 that includes a substrate (e.g., semiconductor substrate) 102. The substrate may be integrated with electronic circuitry (e.g., transistors). A seed layer (e.g., TiW and/or copper) 104 overlies a portion of the substrate 102 and acts as an adhesive. A conductive structure 106 (e.g., copper) overlies the seed layer 104 where the seed layer 104 facilitates adhering the conductive structure 106 to the substrate 102. An insulator layer 108 (e.g., polyimide) overlies the substrate 102 and a portion of the conductive structure 106. A tapered opening 110 is defined in the insulator layer 108 over a portion of the conductive structure 106. The electronic device 100 further includes a flanged conductive column 112 (e.g., copper column) that is disposed in the tapered opening 110 of the insulator layer 108. An optional encapsulation material layer (e.g., laminate, mold compound) 114 is formed over the insulator layer 108 and surrounds the flanged conductive column 112. A mounting surface 116 of the flanged conductive column 112 extends above a top surface 118 of the encapsulation material layer 114 such that the mounting surface 116 of the flanged conductive column 112 is exposed to thereby provide a conductive contact for mounting the electronic device 100 to an external device (e.g., printed circuit board). The mounting surface 116 of the flanged conductive column 112 may extend above the top surface 118 of the encapsulation material layer 114 in a range from approximately 15-20 um.

The flanged conductive column 112 includes a base portion 120, a flanged portion 122, and an outer conductive coating (e.g., solder) 124. The outer conductive coating 124 coats both the base portion 120 and the flanged portion 122 and also coats the mounting surface 116 of the flanged conductive column 112, which eliminates the need for adding solder when mounting the electronic device 100 to a PCB. The base portion 120 is disposed in the tapered opening 110 and connects to the conductive structure 106 via solder 126. Thus, the conductive structure 106 provides a connection from the substrate 102 to the flanged conductive column 112. In one example, the base portion 120 and the flanged portion 122 can be have a rectangular or square shape.

Referring to FIG. 1B, in this example, the base portion 120 of the flanged conductive column 112 has width w and a depth d that is less than a width W and a depth D of the flanged portion 122. Thus, the flanged conductive column 112 has a T-shaped cross-section. The width w and depth d of the base portion 120 can range from 0.05 mm to 0.30 mm. The width W and depth D of the flanged portion 122 can range from 0.10 mm to 0.40 mm. In addition, an overall height of the flanged conductive column 112 can range from 0.10 mm to 0.30 mm where a thickness of the flanged portion 122 can range from 0.03 mm to 0.10 mm. Thus, a height of the base portion 120 can range from 0.70 mm to 0.20 mm.

In another example, the flanged conductive column 112 can have a circular cross-section. Thus, the base portion 120 and the flanged portion 122 can be circular where a diameter of the base portion 120 is less than a diameter of the flanged portion 122. A diameter of the base portion 120 can range from 0.05 mm to 0.30 mm and a diameter of the flanged portion 122 can range from 0.10 mm to 0.40 mm. As above, the overall height of the flanged conductive column 112 can range from 0.10 mm to 0.30 mm where the thickness of the flanged portion 122 can range from 0.03 mm to 0.10 mm. Thus, the height of the base portion 120 can range from 0.70 mm to 0.20 mm.

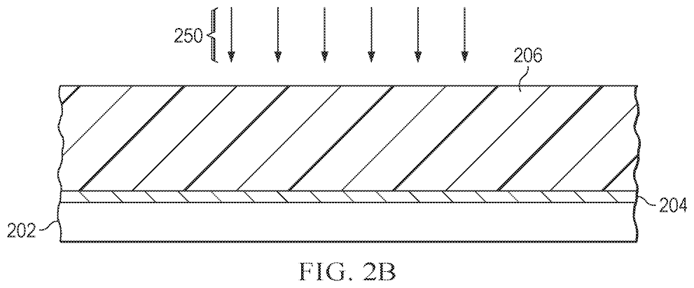

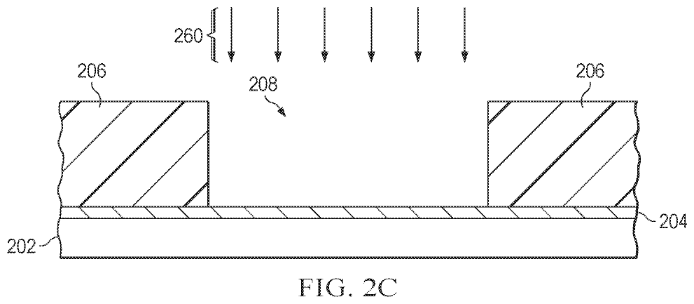

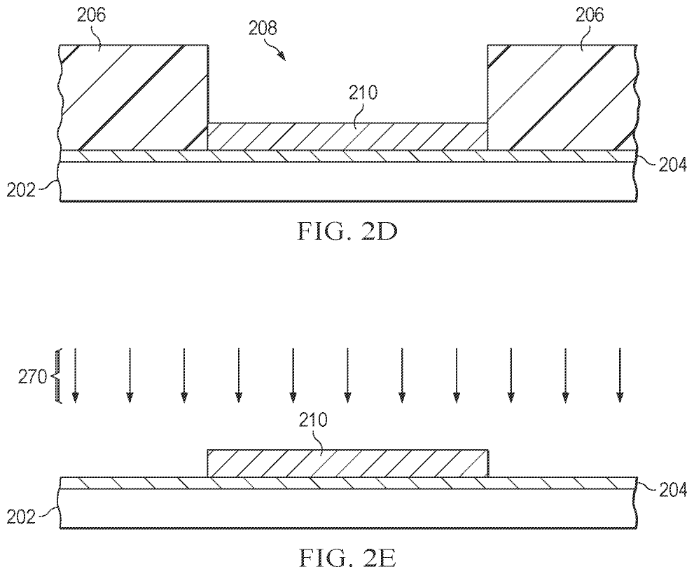

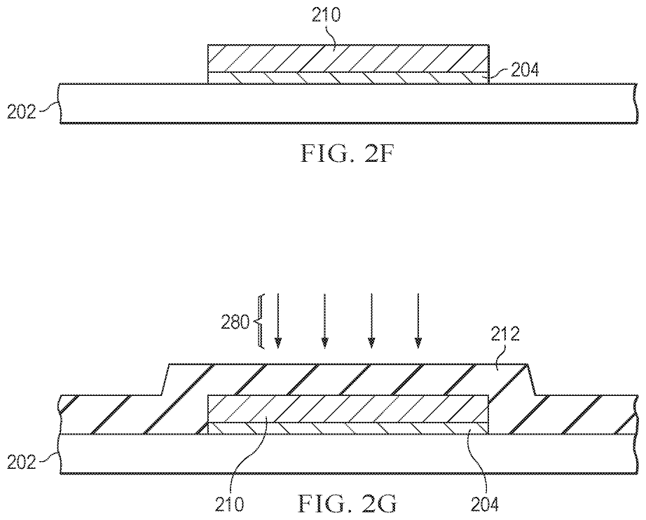

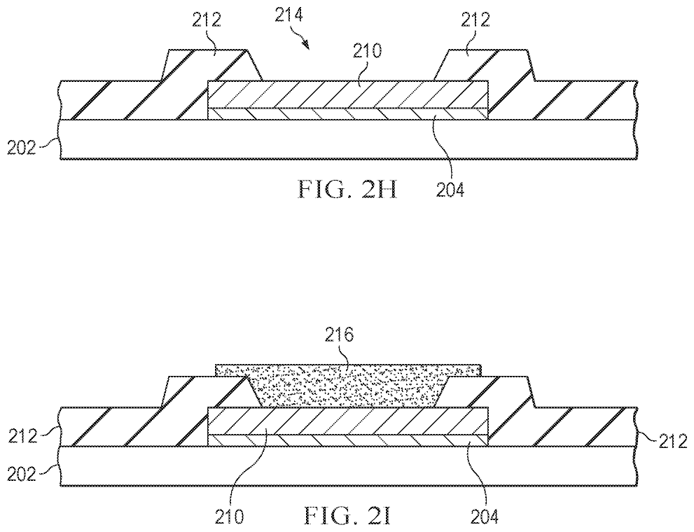

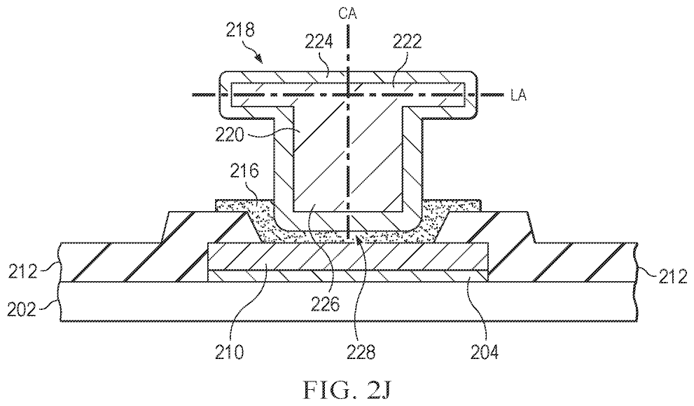

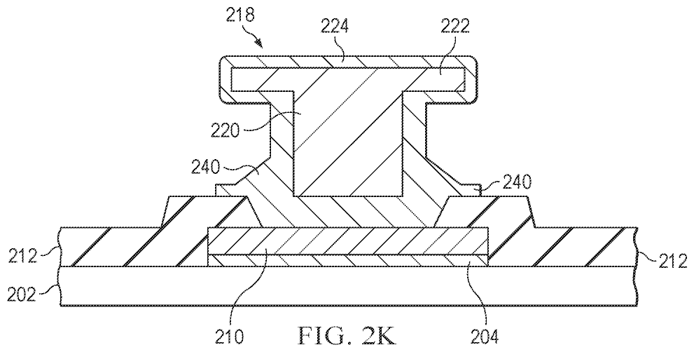

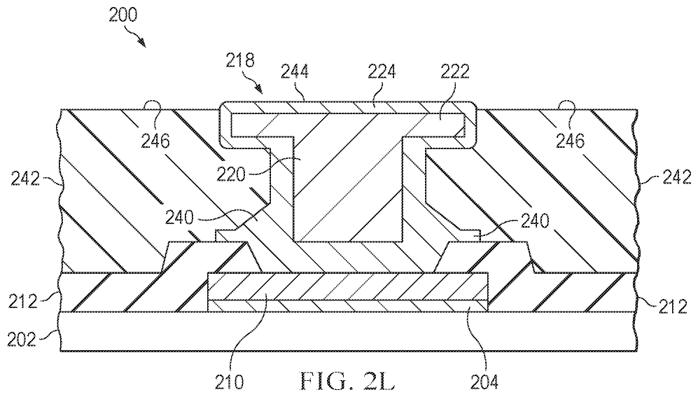

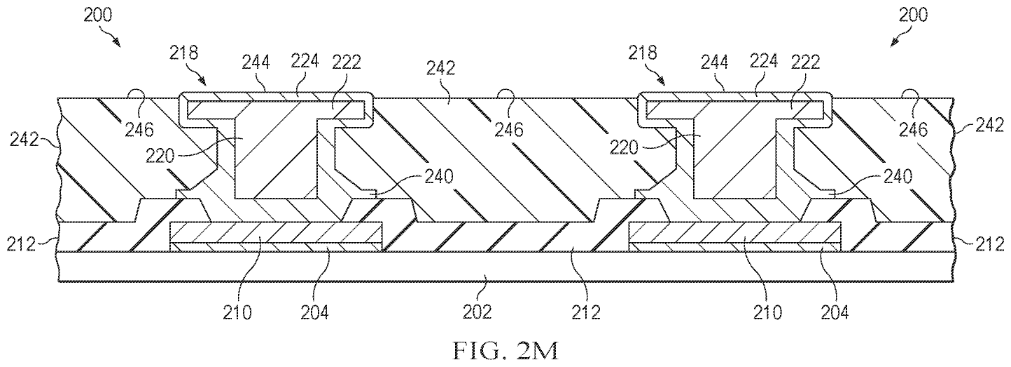

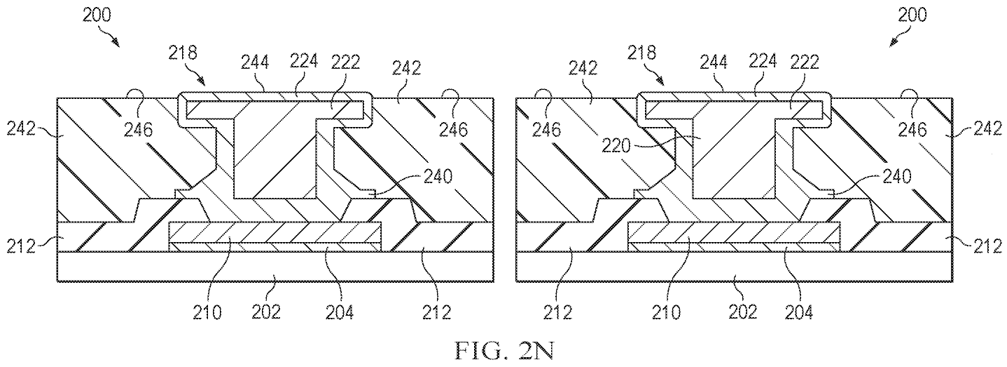

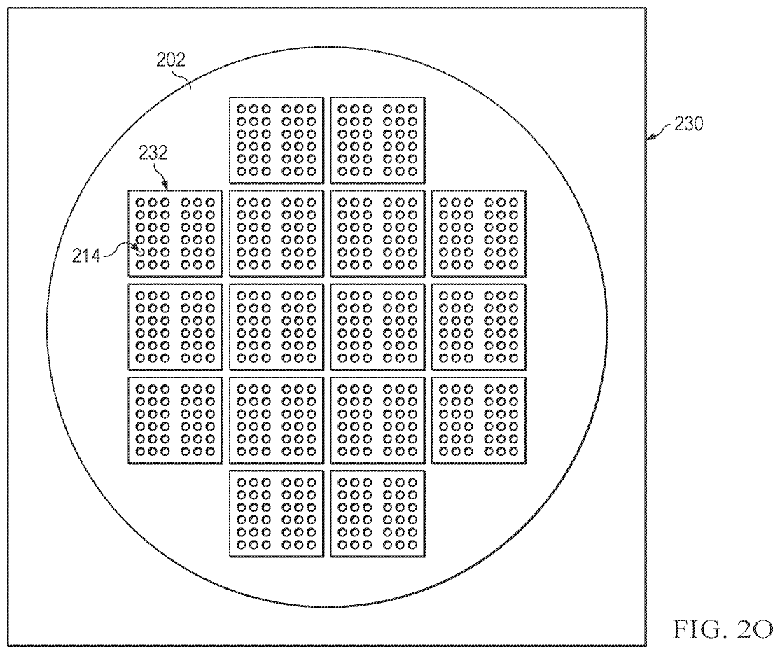

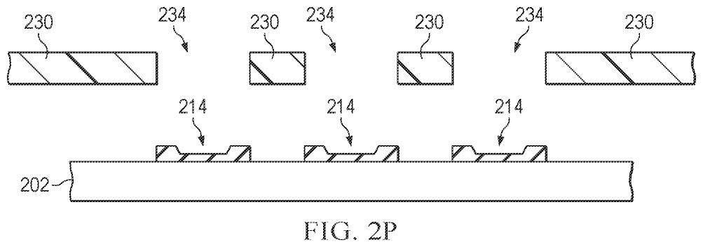

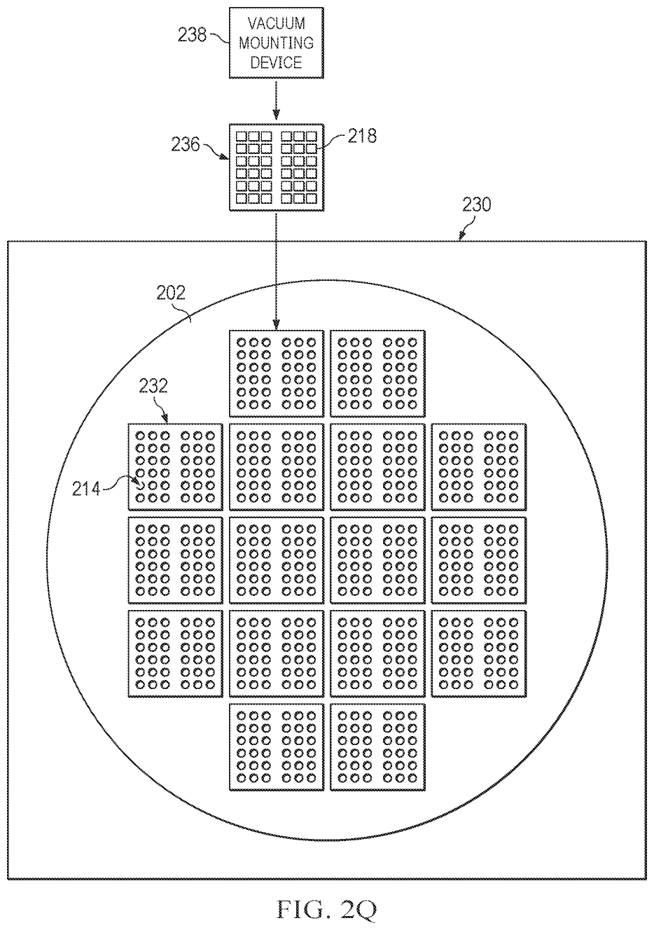

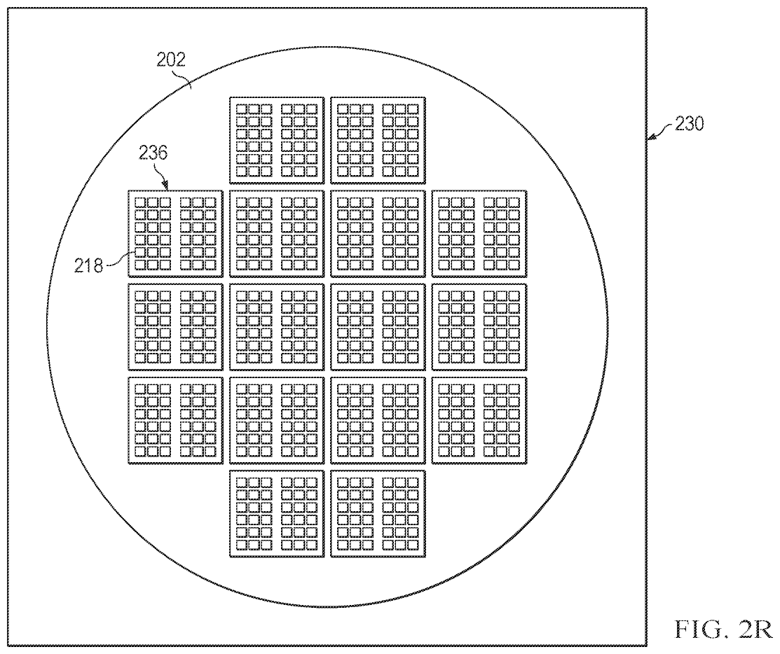

FIGS. 2A-2N illustrate a fabrication process associated with the formation of the electronic device 100 illustrated in FIG. 1A. Though depicted sequentially as a matter of convenience, at least some of the actions shown can be performed in a different order and/or performed in parallel. Alternatively, some implementations may perform only some of the actions shown. Still further, although the example illustrated in FIGS. 2A-2N is an example method illustrating the example configuration of FIG. 1A, other methods and configurations are possible. It is understood that although the method illustrated in FIGS. 2A-2L depicts the fabrication process of a single electronic device and FIGS. 2M-2N depict a singulation process of two electronic devices, the process applies to an array of electronic devices. Thus, after fabrication of the array of electronic device the array is singulated to separate each electronic device from the array.

Referring to FIG. 2A, the fabrication process of an electronic device begins with a substrate such as a semiconductor substrate (e.g., silicon wafer) 202 and a seed layer 204 deposited on a surface of the substrate 202. A photoresist material layer 206 is formed over the seed layer 204 resulting in the configuration in FIG. 2B. The photoresist material layer 206 is patterned 250 to form an opening 208 resulting in the configuration in FIG. 2C. The configuration in FIG. 2C undergoes an electroplating process 260 to deposit a conductive structure 210 into the opening 208 of the photoresist material layer 206 and onto an exposed portion of the seed layer 204 resulting in the configuration in FIG. 2D. The photoresist material layer 206 is stripped resulting in the configuration in FIG. 2E. The configuration in FIG. 2E undergoes an etching process 270 to strip portions of the seed layer 204 not covered by the conductive structure 210 resulting in the configuration in FIG. 2F.

An insulator layer (e.g., polyimide) 212 is formed over the substrate 202 and conductive structure 210 resulting in the configuration in FIG. 2G. The insulator layer 212 is etched 280 to form a tapered opening 214 over a portion of the conductive structure 210 thereby exposing the conductive structure 210 resulting in the configuration in FIG. 2H. The insulator layer 212 is cured after formation of the tapered opening 214. Flux 216 is deposited via a printing process into the tapered opening 214 and onto the conductive structure 210 to facilitate a downstream soldering process resulting in the configuration in FIG. 2I.

A flanged conductive column 218 (e.g., copper column) comprised of a base portion 220, a flanged portion 222, and an outer conductive layer (e.g., solder) 224 is deposited into the flux 216 residing in the tapered opening 214 of the insulator layer 212 resulting in the configuration in FIG. 2J. Specifically, as described further below relating to FIGS. 2O-R, the flanged conductive column 218 is deposited into the flux 216 such that a bottom part 226 of the base portion 220 contacts the flux 216, but does not contact the conductive structure 210 thereby forming a gap 228 between the bottom part 226 of the base portion 220 and the conductive structure 210. Once deposited, a central axis CA of the flanged conductive column 218 is substantially perpendicular to the substrate 202 and the conductive structure 210, and a longitudinal axis LA of the flanged portion 222 is substantially parallel to the substrate 202 and the conductive structure 210, as illustrated in FIG. 2J.

Additional solder 240 is deposited into the tapered opening 214 and onto a portion of the insulator layer 212. A solder reflow process and flux wash are performed to join the flanged conductive column 218 to the conductive structure 210 and to remove any residual flux 216 resulting in the configuration in FIG. 16. An optional encapsulation material layer (e.g., laminate, mold compound) 242 is formed over the insulator layer 212 and surrounds the flanged conductive column 218 resulting in the configuration in FIG. 2L. The encapsulation material layer 242 is formed such that a mounting surface 244 of the flanged conductive column 218 extends above a top surface 246 of the encapsulation material layer 242 such that the mounting surface 244 of the flanged conductive column 218 is exposed to thereby provide a conductive contact for mounting the electronic device 200 to an external device (e.g., printed circuit board). The mounting surface 244 of the flanged conductive column 218 may extend above the top surface 246 of the encapsulation material layer 242 in a range from approximately 15-20 um. In some examples, the encapsulation material layer 242 can be formed by a laminating printing process, by a mold compound flow process, or by using Ajinomoto Build Up Film (ABF). Although not necessary to expose the mounting surface 244 of the flanged conductive column 218, the electronic device 200 may be back grinded to meet required package dimensions (e.g., thickness).

As mentioned above, although the method described herein and illustrated in the figures depicts the fabrication process of a single electronic device, the process applies to the fabrication of an array of electronic devices. For simplicity, FIG. 2M is an illustration of a pair of electronic devices 200 prior to singulation and FIG. 2N is an illustration of the electronic devices of FIG. 2M after singulation. Thus, after fabrication of the array of electronic devices 200 the array is singulated to separate each electronic device 200 from the array.

Referring to FIGS. 2O-2R, in one example, the flanged conductive column 218 may be deposited via a pick and place process, where an array of the flanged conductive columns 218 are picked by a vacuum process and placed into the tapered openings 214 formed in the insulator layer 212 with the use of a stencil 230. The stencil 230 is placed over the substrate 202 containing an array 232 of electronic devices 200 as shown in FIG. 2O. The stencil 230 has openings 234 that align with the tapered openings 214 of the insulator layer 212 as shown in a cross-sectional view in FIG. 2P. FIG. 2Q illustrates a process of picking and placing an array 236 of the flanged conductive columns 218 onto the substrate 202. A vacuum mounting device 238 picks up the array 236 of flanged conductive columns 218 via a vacuum and places each array 236 of flanged conductive columns 218 onto each array 232 of electronic devices 200 resulting in the configuration in FIG. 2R.

In another example, the flanged conductive column 218 may be deposited via a brushing process where the flanged conductive column 218 is placed in close proximity to the substrate 202 and brushed into the tapered opening 214 in the insulator layer 212. A similar stencil is used that ensures that the base portion 220 is deposited into the tapered opening 214 in the insulator layer 212.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a semiconductor substrate;
a conductive structure disposed over the semiconductor substrate;
an insulator layer overlying the semiconductor substrate with a tapered opening overlying a portion of the conductive structure; and
a flanged conductive column having a base portion disposed in the tapered opening and coupled to the portion of the conductive structure and a flanged portion being configured to be exposed to provide a conductive contact to the electronic device.

2. The electronic device of claim 1, wherein the flanged conductive column comprises a solder coated flanged copper column.

3. The electronic device of claim 2, wherein each of the base portion and the flanged portion of the solder coated flanged conductive column have a generally rectangular prism shape.

4. The electronic device of claim 1, wherein the semiconductor substrate contains electronic circuitry and is formed from a portion of a semiconductor wafer.

5. The electronic device of claim 1, wherein the insulator layer is formed from polyimide (PI).

6. The electronic device of claim 1, further comprising an encapsulation material layer that overlies the insulator layer and encapsulates the flanged conductive column leaving a mounting surface of the flanged conductive column exposed and extending beyond the encapsulation material layer to provide a conductive contact to the electronic device.

7. The electronic device of claim 6, wherein the encapsulation material layer is a laminate.

8. The electronic device of claim 6, wherein the encapsulation material layer is a mold compound.

9. A method of forming an electronic device, the method comprising:
forming a conductive structure over a semiconductor substrate;
depositing an insulator layer over the conductive structure and the semiconductor substrate;
etching a tapered opening in the insulator layer overlying the conductive structure;
providing a flanged conductive column having a base portion and a flanged portion;
disposing the base portion of the flanged conductive column in the tapered opening with the tapered opening extending outward away from the conductive structure to form a conductive contact of the electronic device; and
performing a solder reflow process on the electronic device to align and solder the base portion of the flanged conductive column to the conductive structure.

10. The method of claim 9, wherein the conductive column comprise a solder coated copper column, the solder of the base portion binding to solder in the solder reflow process, and the solder on the flanged portion being configured to bind to contacts on a substrate or device which the electronic device is being bonded to for an end use.

11. The method of claim 9, wherein the semiconductor substrate is a portion of a semiconductor wafer and further comprising forming electronic circuitry in the semiconductor substrate.

12. The method of claim 9, wherein the disposing the base portion of the flanged conductive column in the tapered opening comprises brushing the flanged conductive column into the tapered opening.

13. The method of claim 9, wherein the disposing the base portion of the flanged conductive column in the tapered opening is accomplished via vacuum.

14. The method of claim 9, further comprising encapsulating the flanged conductive column with an encapsulation material layer covering the insulator layer, the base portion and a portion of the flanged portion of the flanged conductive column leaving a mounting surface of the flanged conductive column exposed and extending beyond the encapsulation material layer to provide a conductive contact to the electronic device.

15. The method of claim 14, wherein the encapsulation material layer is one of a laminate and a mold material.

16. The method of claim 14, further comprising grinding a back surface of the semiconductor substrate to a desired thickness.

17. A method of forming a plurality of electronic devices, the method comprising:
forming respective conductive structures associated with respective electronic devices over a semiconductor wafer;
depositing an insulator layer over the respective conductive structures and the semiconductor wafer;
etching tapered openings in a portion of the insulator layer overlying associated respective conductive structures associated with respective electronic devices;
providing a plurality of solder coated flanged conductive columns with each having a base portion and a flanged portion;
disposing the base portion of the flanged conductive columns in respective tapered openings with tapered portions extending outward away from the respective conductive structure to form a conductive contact of a respective electronic device;
performing a solder reflow process to align and solder the base portions of the respective flanged conductive columns to the respective conductive structures;
encapsulating the flanged conductive columns with an encapsulation material layer covering the insulator layer, the base portion and a portion of the flanged portion of the respective flanged conductive columns leaving a mounting surface of the flanged conductive columns exposed and extending beyond the encapsulation material layer to provide a conductive contact to the respective electronic devices; and
singulating electronic devices by cutting through the encapsulation material layer, the insulating layer and semiconductor wafer to form individual electronic devices.

18. The method of claim 17, further comprising forming respective electronic circuitry in the semiconductor wafer for each of the individual electronic devices.

19. The method of claim 17, wherein the disposing the base portion of the flanged conductive columns for each of the plurality of solder coated flanged conductive columns is accomplished via one of a vacuum process and a brushing process.

20. The method of claim 17, wherein the encapsulation material layer is one of a laminate and a mold material.
